(19) United States
(12) Patent Application Publication
(10) Pub. No.: US 2026/0109800 A1
(43) Pub. Date: Apr. 23, 2026

(54) ULTRAVIOLET-CURABLE COMPOSITION AND USE THEREOF

(71) Applicant: DOW TORAY CO., LTD., Shinagawa-Ku, Tokyo (JP)

(72) Inventors: Tomoka HOSOKAWA, Ichihara-Shi, Chiba (JP); Takuya OGAWA, Ichihara-shi, Chiba (JP)

(21) Appl. No.: 19/114,312

(22) PCT Filed: Sep. 19, 2023
(86) PCT No.: PCT/JP2023/033997

§ 371 Date: Dec. 16, 2025

(30) Foreign Application Priority Data
Sep. 22, 2022 (JP) 2022-151783

(51) Int. Cl. C08F 283/12; C09D 4/06; C09D 151/08; C09J 4/06; C09J 151/08; H10K 59/80

(52) U.S. Cl. CPC C08F 283/12; C09D 4/06; C09D 151/085; C09J 4/06; C09J 151/085; H10K 59/873

(57) ABSTRACT

Provided is an ultraviolet-curable composition containing silicon atoms, wherein the composition has a high ability to adjust the mechanical properties of the cured product thereof, and has excellent workability and high adhesion to a substrate even for solvent-free application. This disclosure provides an ultraviolet-light curable composition and a use thereof. The composition contains: (A) 1-99 parts by mass of a compound having at least one (meth)acryloxy group and hydroxyl group in one molecule and having no silicon atom; (B) 1-99 parts by mass of an organopolysiloxane having at least two alkenyl groups in one molecule and having no ultra-violet-curable functional group; and (C) 0-80 parts by mass of a compound having at least one (meth)acryloxy group in the molecule and having no hydroxyl group, on the basis of 100 parts by mass of the total mass of the composition, and contains substantially no organic solvent in the composition.

The present invention relates to an ultraviolet light curable composition curable by actinic rays, such as ultraviolet rays or electron beam, particularly an ultraviolet light curable composition containing an organosilicon compound, preferably an organopolysiloxane, and more particularly to an ultraviolet light curable composition in which a cured product obtained therefrom has low viscosity and excellent coatability. The curable composition of the present invention is suitable as an insulating material for electronic and electrical devices, and particularly as a material for use as a coating agent, or optical adhesive. Furthermore, the composition has excellent application properties and superior wettability to substrates, thus being useful as an injection molding material and inkjet printing material.

### CONVENTIONAL TECHNOLOGY

Due to high heat resistance and excellent chemical stability, silicone resins have been used as coating agents, potting agents, insulating materials, and the like for electronic and electrical devices. Silicone resins are reported to include ultraviolet light curable silicone compositions.

Touch panels are used in various display devices such as mobile devices, industrial equipment, car navigation systems, and the like. In order to improve detection sensitivity, electrical influence from light emitting sites such as light-emitting diodes (LED), organic EL devices (OLED), and the like must be suppressed, and an insulating layer is usually disposed between the light-emitting part and the touchscreen.

On the other hand, thin display devices such as OLEDs and the like have a structure in which a plurality of functional thin layers are stacked. In recent years, studies have been started in order to improve the overall reliability of display devices, particularly flexible display devices, by laminating an insulating layer with high flexibility onto the touchscreen layer. In addition, the inkjet printing method has been adopted as a processing method for organic layers to improve productivity. Therefore, a material that can be processed by the inkjet printing method is required for the aforementioned insulating layer.

Japanese Unexamined Patent Application 2016-56330 discloses an ultraviolet light curable organopolysiloxane composition containing a polysiloxane having a methacryloxy functional group, a polysiloxane having two or more acryloxy functional groups in one molecule, and a polysiloxane containing alkenyl groups at both ends, and also discloses a silicone gel cured product obtained from the composition. This composition has high viscosity, so there are restrictions on the processing methods, and application by an injection molding method or inkjet method is not possible.

Furthermore, International Patent Application WO2018-3381 discloses an inkjet ink composition containing an ultraviolet light curable silicone composition containing: a polysiloxane having two (meth)acryloxy functional groups in one molecule; and an acrylate compound that does not contain a siloxane structure. The viscosity of the composition disclosed therein is not sufficiently low, and there is a problem in applying the composition by an inkjet method. Furthermore, the composition has a high content of silicone components, so there is a problem with adhesion to the substrate.

### RELATED ART DOCUMENTS

### Patent Documents

Patent Document 1: Japanese Unexamined Patent Application 2016-56330
Patent Document 2: WO2018-3381

### SUMMARY OF THE INVENTION

### Problem to be Solved by the Invention

As described above, several ultraviolet light curable compositions containing an organopolysiloxane having an acryloxy functional group are well known, but there is still a need for ultraviolet light curable compositions that allow easy adjustment of the mechanical properties of the cured product and have excellent workability, especially low viscosity, for application to substrates. The present invention provides a silicon-atom-containing curable composition, particularly an ultraviolet light curable composition, which is a solvent-free agent that has excellent workability when applied to a substrate, has a high ability to adjust the mechanical properties of the product obtained by curing, and also has good adhesive properties.

### Means for Solving the Problem

The present invention was achieved by a discovery that the ultraviolet light curable composition obtained by concomitant use of:
(A) 1 to 99 parts by mass of a compound having one or more (meth)acryloxy groups and hydroxyl groups in each molecule and having no silicon atoms;
(B) 1 to 99 parts by mass of an organopolysiloxane having two or more alkenyl groups in each molecule and having no ultraviolet light curable functional groups; and
(C) 0 to 80 parts by mass of a compound having one or more (meth)acryloxy groups in each molecule and having no hydroxyl groups;
based on 100 mass parts of the total mass of the composition,
has low viscosity even when the composition is substantially free of organic solvent, so the workability is excellent when applying to a substrate, excellent mechanical properties can be adjusted, and favorable adhesion can be demonstrated in the cured product.

The present invention relates to an ultraviolet light curable composition containing an organosilicon compound, particularly an ultraviolet light curable organopolysiloxane composition, and the composition is cured by an ultraviolet light curable functional group forming a bond. However, the curing method is not limited to ultraviolet light irradiation, and an arbitrary method in which an ultraviolet light curable functional group can cause a curing reaction can be used. For example, electron beam irradiation may be used to cure the composition of the present invention.

The ultraviolet light curable composition of the present invention contains:
(A) 1 to 99 parts by mass of a compound having one or more (meth)acryloxy groups and hydroxyl groups in each molecule and having no silicon atoms;
(B) 1 to 99 parts by mass of an organopolysiloxane having two or more alkenyl groups in each molecule and having no ultraviolet light curable functional groups; and
(C) 0 to 80 parts by mass of a compound having one or more (meth)acryloxy groups in each molecule and having no hydroxyl groups;
based on 100 mass parts of the total mass of the composition,
wherein the composition is substantially free of organic solvent.
Note that unless otherwise specified herein, the viscosity of a substance is the value measured using an E-type viscometer at 25° C.

Component (A) in the curable composition is preferably a compound expressed by the following formula (1A) or (1B).

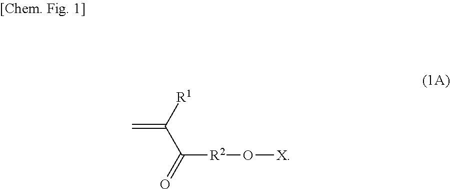

(In the formulas, R¹ is a hydrogen atom or a methyl group, R² is a divalent linking group expressed by the following formula (2A), X is a hydrogen atom, an alkyl group having 1 to 20 carbon atoms, a cycloalkyl group, an arylalkyl group, an aryl group, or a (meth)acrylic group, R³ is a hydrogen atom, a methyl group, or an ethyl group, y is a hydroxyl group or a hydroxymethyl group, a is an integer from 0 to 3, b is 0 or 1, c is an integer from 0 to 3, d is an integer from 0 to 5, and * is a bonding site to the carbonyl group. However, one or more hydroxyl group is included in each molecule)

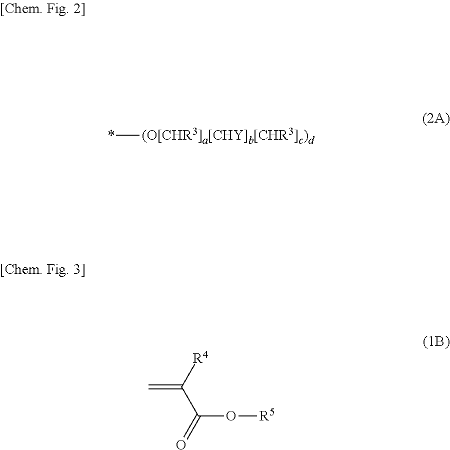

(In the formula, R⁴ is a monovalent group expressed by the following formula (2B), R⁵ and R⁶ independently represent an alkyl group, a cycloalkyl group, an arylalkyl group, or an aryl group having 1 to 20 carbon atoms, e is an integer from 0 to 3, and ** is a bonding site to a carbon-carbon double bond)

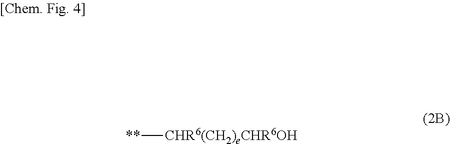

The viscosity of the entire composition measured at 25° C. using an E-type viscometer is preferably 500 mPa·s or less.

Component (B) is preferably a linear, branched, or cyclic organopolysiloxane expressed by the average compositional formula:

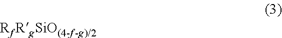

(wherein, R is an alkenyl group;
R′ represents a group selected from monovalent hydrocarbon groups excluding alkenyl groups, hydroxyl groups, and alkoxy groups;
f and g are numbers that satisfy the following conditions: 1≤f+g≤3 and 0.05≤f/(f+g)≤1.0; and there are at least two R in each molecule)

The organopolysiloxane of component (B) is preferably one or more type of organopolysiloxane having at least 2 alkenyl groups in each molecule, selected from the group consisting of organopolysiloxane expressed by formula (4)

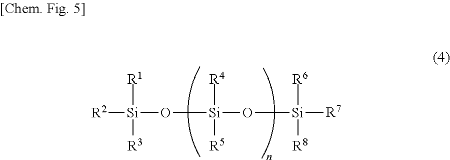

(wherein, of all R¹ to R⁸ groups, at least two alkenyl groups are present in each molecule; the remaining R¹ to R⁸ are independently an unsubstituted or fluorine-substituted monovalent hydrocarbon group, a hydroxyl group, or an alkoxy group; and n is a number 0 to 1000, inclusively);
branched organopolysiloxane expressed by average unit formula (5):

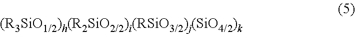

(wherein each R is independently a group selected from alkenyl groups and unsubstituted or fluorine-substituted monovalent hydrocarbon groups, at least two of all R are alkenyl groups, (j+k) is a positive number, h is 0 or a positive number, and i is a number in a range of 0 to 100); and
cyclic organopolysiloxane expressed by the following formula (6):

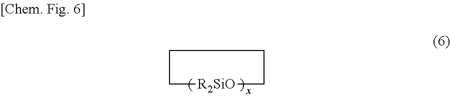

(wherein each R is independently a group selected from alkenyl groups and unsubstituted or fluorine-substituted monovalent hydrocarbon groups, x is an integer from 3 to 10, and at least two alkenyl groups are provided in each molecule) as well as mixtures of these organopolysiloxanes.

Component (B) may be an organopolysiloxane expressed by formula (4) or (5).

Component (B) may be an organopolysiloxane having an aromatic hydrocarbon group having 6 to 20 carbon atoms.

Component (C) may be a compound having one (meth)acryloxy group, or a mixture of two or more compounds having one (meth)acryloxy group.

Component (C) may be one or more compounds having one (meth)acryloxy group, one or more compounds having two or more (meth)acryloxy groups, or a mixture of one or more compounds having one (meth)acryloxy group and one or more compounds having two or more (meth)acryloxy groups.

A portion or all of the above components (A) and (C) may be a compound having an acryloxy group.

Component (A) may be a hydroxyalkyl (meth)acrylate.

The amount of aromatic hydrocarbon groups having 6 to 20 carbon atoms in the above component (B) is preferably 10 mol % or more of all substituents on silicon atoms.

The viscosity of the entire composition measured at 25° C. using an E-type viscometer is preferably in a range of 5 to 60 mPa·s or less.

The number of moles of hydroxyl groups per 100 g of the total composition is preferably 5 mmol or more and 150 mmol or less.

The present invention further provides an insulating coating agent or insulating adhesive containing the aforementioned ultraviolet light curable composition. The ultraviolet light curable composition of the present invention is useful as an insulating coating agent or insulating adhesive.

The present invention further provides a cured product of the aforementioned ultraviolet light curable composition. Furthermore, the present invention also provides a method of using the cured product as an insulating coating layer or insulating adhesive layer.

The present invention further provides a display device such as a liquid crystal display, organic EL display, or organic EL flexible display that includes a layer containing a cured product of the aforementioned ultraviolet light curable composition.

### DESCRIPTION OF THE PREFERRED EMBODIMENTS

A configuration of the present invention will be further described in detail below. The ultraviolet light curable composition of the present invention contains as curable essential components:
(A) 1 to 99 parts by mass of a compound having one or more (meth)acryloxy groups and hydroxyl groups in each molecule and having no silicon atoms;
(B) 1 to 99 parts by mass of an organopolysiloxane having two or more alkenyl groups in each molecule and having no ultraviolet light curable functional groups; and
(C) 0 to 80 parts by mass of a compound having one or more (meth)acryloxy groups in each molecule and having no hydroxyl groups;
based on 100 mass parts of the total mass of the composition;
furthermore, if necessary, various components can be included, selected from photoradical polymerization initiators and various other additives. However, the composition of the present invention is substantially free of organic solvent.

In the present specification, the term “polysiloxane” refers to a siloxane unit (Si—O) with a degree of polymerization of two or more, in other words with an average of two or more Si—O bonds per molecule. Polysiloxanes include siloxane oligomers such as disiloxanes, trisiloxanes, tetrasiloxanes, and the like, as well as siloxane polymers with higher degrees of polymerization.

### Component (A)

Component (A) is a compound having one or more (meth)acryloxy groups and hydroxyl groups in each molecule and having no silicon atoms. There is no limitation on the molecular structure so long as this objective can be achieved, and the structure can be linear, branched, cyclic, box-shaped, or any other type. In the present specification, “(meth)acryloxy group” refers to “a group selected from methacryloxy groups and acryloxy groups”. Furthermore, compounds having a (meth)acryloxy group include both methacrylate compounds and acrylate compounds.

Component (A) has a hydroxyl group in each molecule, and may be one or more compounds having one (meth)acryloxy group, one or more compounds having two or more (meth)acryloxy groups, or a mixture of one or more compounds having one (meth)acryloxy group and one or more compounds having two or more (meth)acryloxy groups. At least one compound having one (meth)acryloxy group is preferably used.

Component (A) has a (meth)acryloxy group and a hydroxyl group in the molecule, so the viscosity can be easily adjusted, and the cured product of the ultraviolet light curable composition according to the present invention obtained using component (A) can be provided with good adhesion to a substrate, in particular, strong adhesive strength. In addition, component (A) has a reactive functional group, so even if blended in a relatively large amount, component (A) is incorporated into the curing system without the problem of bleed-out, and has the advantage of providing a cured product with high adhesive strength. When a (meth)acryloxy group-containing compound not having a hydroxyl group is used [for example, when component (B) and component (C) are used in combination], the resulting cured product may not be able to achieve sufficient adhesion and adhesive strength to the substrate.

Furthermore, component (A) preferably has one or two (meth)acryloxy groups per molecule. In compounds having two (meth)acryloxy groups, the functional groups may be any combination of (i) two acryloxy groups, (ii) two methacryloxy groups, or (iii) one acryloxy group and one methacryloxy group.

Component (A) preferably has a viscosity at 25° C. of 1 to 500 mPa·s, more preferably 1 to 100 mPa·s, and particularly preferably 1 to 50 mPa·s. When component (A) is a mixture of two or more compounds, the viscosity of the mixture is preferably within the above range.

Furthermore, component (A) is preferably a compound having at least one acryloxy group or a mixture containing the same. Furthermore, component (A) may be a mixture of two or more types of compounds having an acryloxy group.

Component (A) is preferably a compound expressed by the following formula (1A) or (1B).

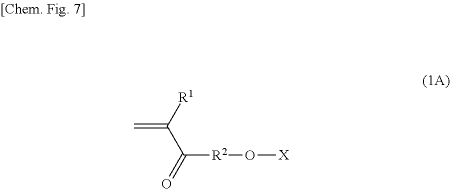

(In the formulas, R¹ is a hydrogen atom or a methyl group, R² is a divalent linking group expressed by the following formula (2A), X is a hydrogen atom, an alkyl group having 1 to 20 carbon atoms, a cycloalkyl group, an arylalkyl group, an aryl group, or a (meth)acrylic group, R³ is a hydrogen atom, a methyl group, or an ethyl group, y is a hydroxyl group or a hydroxymethyl group, a is an integer from 0 to 3, b is 0 or 1, c is an integer from 0 to 3, d is an integer from 0 to 5, and * is a bonding site to the carbonyl group. However, one or more hydroxyl group is included in each molecule)

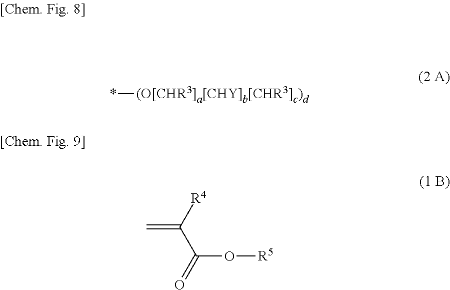

(In the formula, R⁴ is a monovalent group expressed by the following formula (2B), R⁵ and R⁶ independently represent an alkyl group, a cycloalkyl group, an arylalkyl group, or an aryl group having 1 to 20 carbon atoms, e is an integer from 0 to 3, and ** is a bonding site to a carbon-carbon double bond)

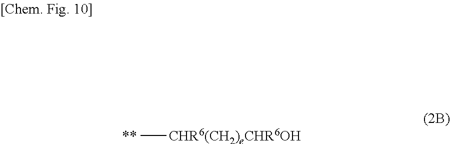

R¹ represents a hydrogen atom or a methyl group. As mentioned above, R¹ is preferably a hydrogen atom. X is a hydrogen atom, an alkyl group having 1 to 20 carbon atoms, a cycloalkyl group, an arylalkyl group, an aryl group, or a (meth)acrylic group. Examples of alkyl groups having 1 to 20 carbon atoms include methyl, ethyl groups, n-propyl groups, isopropyl groups, n-butyl groups, tert-butyl groups, sec-butyl groups, pentyl groups, hexyl groups, and octyl groups, with methyl groups being preferred.

Examples of cycloalkyl groups include cyclopentyl groups, cyclohexyl groups, and the like. Examples of arylalkyl groups include benzyl groups, phenylethyl groups, and the like. Examples of aryl groups include phenyl groups and naphthyl groups, but phenyl groups are preferred.

On the other hand, R² is a divalent linking group expressed by the above formula (2A). Here, R³ is independently a hydrogen atom, a methyl group, or an ethyl group, but a hydrogen atom or a methyl group is preferable. Furthermore, the substituent Y on R² is a hydroxyl group or a hydroxymethyl group.

Further, a in R² is an integer from 0 to 3, b is 0 or 1, c is an integer from 0 to 3, and d is an integer from 0 to 5.

On the other hand, R⁴ is a monovalent group expressed by the above formula (2B). R⁵ and R⁶ in the above formula (2B) are each independently an alkyl group, a cycloalkyl group, an arylalkyl group, or an aryl group having 1 to 20 carbon atoms, and the groups exemplified above can be used. Additionally, e is an integer from 0 to 3.

By appropriately selecting a to e and the substituents R¹ to R⁶, X, and Y defined herein, the molecular weight, viscosity, number of hydroxyl groups in the molecule, hydrophilicity, ultraviolet light curing properties, and the like of component (A) can be controlled, and furthermore the physical properties of the cured product obtained by the present invention, particularly the glass transition temperature and adhesion can be adjusted.

The component (A) of the present invention has at least one hydroxyl group in the molecule. Therefore, if X is a group other than a hydrogen atom, b and d are 1 or more, and at least one Y is a hydroxyl group.

Among the compounds that can be used as the above component (A), specific examples of compounds having one (meth)acryloxy group in the molecule include 2-hydroxyethyl acrylate, 2-hydroxyethyl methacrylate, 2-hydroxypropyl acrylate, 2-hydroxypropyl methacrylate, 2-hydroxy-1-methylethyl acrylate, 2-hydroxy-1-methylethyl methacrylate, 4-hydroxybutyl acrylate, 4-hydroxybutyl methacrylate, 2-hydroxybutyl acrylate, 2-hydroxybutyl methacrylate, 4-acryloxyphenol, 4-methacryloyloxyphenol, 1-hydroxymethylpropyl acrylate, 1-hydroxymethylpropyl methacrylate, 6-hydroxyhexyl acrylate, 6-hydroxyhexyl methacrylate, 2-hydroxy-3-phenoxypropyl acrylate, 2-hydroxy-3-phenoxypropyl methacrylate, methyl-2-(2-hydroxy-1-methylethyl)acrylate, methyl-2-(2-hydroxy-1-phenylethyl)acrylate, acrylic acid, methacrylic acid, and the like.

Among the compounds that can be used as component (A), specific examples of compounds having two (meth)acryloxy groups in the molecule include 3-acryloyloxy-2-hydroxypropyl methacrylate, 3-methacryloyloxy-2-hydroxypropyl methacrylate, 3-acryloyloxy-2-hydroxypropyl acrylate, glycerol diacrylate, glycerol dimethacrylate, glycerol-1,3-diglycerolate diacrylate, glycerol-1,3-diglycerolate dimethacrylate, and the like.

The above component (A) may be used alone or in a combination of two or more types, taking into consideration the viscosity, ultraviolet light curability, hardness and glass transition temperature after curing, and adhesiveness of the curable composition. Of these, 2-hydroxybutyl acrylate, 4-hydroxybutyl acrylate, 2-hydroxy-3-phenoxypropyl acrylate, acrylic acid, and 3-acryloyloxy-2-hydroxypropyl methacrylate are preferably used, and 4-hydroxybutyl acrylate, 3-acryloyloxy-2-hydroxypropyl methacrylate, and acrylic acid are particularly preferred compounds.

### Component (B)

Component (B) is an organopolysiloxane that does not have an ultraviolet light curable functional group and has two or more alkenyl groups in the molecule. Component (B) can improve the viscosity and the mechanical strength (particularly toughness and tensile elongation) of the cured product in the entire ultraviolet light curable composition of the present invention, which is substantially solvent-free.

Component (B) can be a linear, branched, or cyclic organopolysiloxane expressed by the average compositional formula:

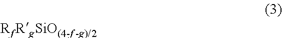

(wherein, R is an alkenyl group;
R′ represents a group selected from monovalent hydrocarbon groups excluding alkenyl groups, hydroxyl groups, and alkoxy groups;
f and g are numbers that satisfy the following conditions: 1≤f+g≤3 and 0.05≤f/(f+g)≤1.0; and there are at least two R in each molecule)

Examples of the alkenyl groups represented by R in formula (1) include alkenyl groups with 2 to 8 carbon atoms, and specifically vinyl groups, allyl groups, butenyl groups, pentenyl groups, hexenyl groups, and octenyl groups. Vinyl groups and hexenyl groups are preferably used.

Linear, branched, or cyclic organopolysiloxanes expressed by the aforementioned average compositional formula have at least two alkenyl groups (R) on average per molecule. The number of alkenyl groups per molecule is preferably 2 to 10, more preferably 2 to 8, on average. In particular, use of a component (B) having alkenyl groups at both molecular chain ends is preferable in order to function as a crosslinking agent and/or a chain extender in a crosslinked structure, and to contribute to improving the rubber properties of the cured product, and particularly elongation and tensile strength.

R′ is a group selected from monovalent hydrocarbon groups, hydroxyl groups, and alkoxy groups, and monovalent hydrocarbon groups include unsubstituted monovalent hydrocarbon groups and fluorine-substituted monovalent hydrocarbon groups. The unsubstituted or fluorine-substituted monovalent hydrocarbon group is preferably a group selected from unsubstituted or fluorine substituted alkyl, cycloalkyl, arylalkyl, and aryl groups having 1 to 20 carbon atoms.

Examples of the alkyl groups above include methyl, ethyl, n-propyl, isopropyl, n-butyl, tert-butyl, sec-butyl, pentyl, hexyl, octyl, and other groups, but methyl groups and hexyl groups are particularly preferable. Examples of the cycloalkyl groups above include cyclopentyl, cyclohexyl, and the like. Examples of the arylalkyl groups above include benzyl, phenylethyl groups, and the like. Examples of the aryl groups above include phenyl groups, naphthyl groups, and the like. Examples of fluorine-substituted monovalent hydrocarbon groups include 3,3,3-trifluoropropyl and 3,3,4,4,5,5,6,6,6-nonafluorohexyl groups. The 3,3,3-trifluoropropyl group is preferred as the fluorine-substituted monovalent hydrocarbon group.

The organopolysiloxane expressed by the above formula (3) has a viscosity at 25° C. of 1 to 25000 mPa·s, or 1 to 5000 mPa·s, but 1 to 5000 mPa·s is most preferable. The viscosity of the organopolysiloxane can be adjusted by changing the ratio of a and b in formula (1), as well as the molecular weight.

The organopolysiloxane expressed by formula (3) preferably has an average of 2 to 1000 silicon atoms, more preferably 2 to 500 silicon atoms, and particularly preferably 2 to 300 silicon atoms per molecule.

In one preferred aspect, the organopolysiloxane of component (B) is a compound expressed by the following formula (4):

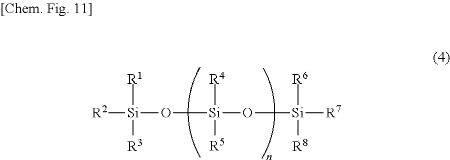

Similar to the aforementioned compound expressed by formula (3), the organopolysiloxane expressed by formula (4) has on average two or more alkenyl groups per molecule.

In formula (4), of all R¹ to R⁸ groups, an average of two or more per molecule are alkenyl groups. The structure of the alkenyl group is not limited to an alkenyl group with a specific chemical structure so long as the structure has a carbon-carbon double bond. The alkenyl group is particularly preferably a terminal alkenyl group, and examples include alkenyl groups with 2 to 20 carbon atoms, such as vinyl groups, allyl groups, butenyl groups, pentenyl groups, hexenyl groups, heptenyl groups, octenyl groups, nonenyl groups, decenyl groups, undecenyl groups, dodecenyl groups, 4-vinylphenyl groups, and the like, but this is not a limitation. The alkenyl-containing group is particularly preferably a group selected from vinyl groups, allyl groups, and hexenyl groups, but vinyl groups and hexenyl groups are particularly preferable.

In formula (4), R¹ to R⁸ other than the ultraviolet light curable functional group are independently an unsubstituted or fluorine-substituted monovalent hydrocarbon group, and preferably a group selected from unsubstituted or fluorine substituted alkyl, cycloalkyl, arylalkyl, and aryl groups having 1 to 20 carbon atoms. The aforementioned groups can be applied thereto.

In formula (4), n is a value that causes the organopolysiloxane expressed by formula (4) to have a viscosity at 25° C. of preferably 1 to 25000 mPa·s, more preferably 1 to 5000 mPa·s, and particularly preferably 1 to 3000 mPa·s. A person with ordinary skill in the art can easily determine the value of n without excess trial and error such that the viscosity of the organopolysiloxane of formula (5) is within the aforementioned viscosity range. In general, however, the number of silicon atoms per molecule is preferably 2 to 1000, and particularly preferably 2 to 300, in order for the compound of formula (4) to have the desired viscosity.

The organopolysiloxane of formula (4), which is component (B), has an average of 2 to 10 alkenyl groups per molecule as a whole, preferably 2 to 8, and most preferably 2.

The organopolysiloxane of formula (4) can be used as one type or as a mixture of two or more types. If two or more organopolysiloxanes are used as a mixture, the viscosity of the mixture at 25° C. is preferably within the viscosity range described above.

Furthermore, the aforementioned compound of formula (3) may be a branched organopolysiloxane expressed by the following average unit formula (5).

The branched organopolysiloxane expressed by average unit formula (5):

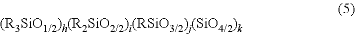

In Formula (6), each R is independently a group selected from alkenyl groups and unsubstituted or fluorine-substituted monovalent hydrocarbon groups, at least two of all R are alkenyl groups, (j+k) is a positive number, h is 0 or a positive number, and i is a number in a range of 0 to 100.

The alkenyl groups and monovalent hydrocarbon groups are defined as above for formula (4). Furthermore, a preferred viscosity of the organopolysiloxane expressed by formula (5) is as specified above for the organopolysiloxane expressed by formula (4).

Furthermore, the alkoxy groups and silanol groups may remain in a molecule in small amounts.

The organopolysiloxane expressed by formula (5) preferably has 4 to 30, and particularly 6 to 20 silicon atoms per molecule.

The number of alkenyl groups of the organopolysiloxane expressed by formula (5) is, as a whole, 2 to 10 on average per molecule, preferably 3 to 10, more preferably 3 to 8, and most preferably 4 to 8 groups.

Furthermore, the aforementioned compound of formula (3) may be a cyclic organopolysiloxane expressed by formula (6)

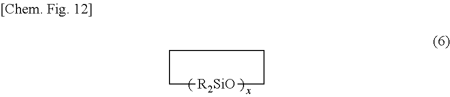

(in formula (6), R is independently a group selected from alkenyl groups and unsubstituted or fluorine-substituted monovalent hydrocarbon groups, x is an integer from 3 to 10, and at least two alkenyl groups are provided in the molecule).

The alkenyl group represented by R in formula (6) and the unsubstituted or fluorine-substituted monovalent hydrocarbon group are as defined for formula (3) above.

Furthermore, a preferred viscosity of the organopolysiloxane expressed by formula (6) is as specified above for the organopolysiloxane expressed by formula (3).

In one preferred embodiment, the above component (B) is an organopolysiloxane having, as at least a portion of the monovalent hydrocarbon groups, an aromatic hydrocarbon group having 6 to 20 carbon atoms as a substituent. Examples of the aromatic hydrocarbon group having 6 to 20 carbon atoms include phenyl groups, tolyl groups, xylyl groups, naphthyl groups, and the like, but phenyl groups are preferred. If component (B) contains an aromatic hydrocarbon group having 6 to 20 carbon atoms, the cured product of the present invention may have improved mechanical strength and improved ultraviolet light curability.

Specific examples of the linear organopolysiloxane expressed by the above formula (3), particularly formula (4), include polydimethylsiloxane terminated with dimethylvinylsilyl groups at both ends, polydimethyl/methylphenylsiloxane copolymer terminated with dimethylvinylsilyl groups at both ends, polydimethyl/diphenylsiloxane copolymer terminated with dimethylvinylsilyl groups at both ends, polymethylphenylsiloxane terminated with dimethylvinylsilyl groups at both ends, polydimethylsiloxane terminated with dimethylhexenylsilyl groups at both ends, polydimethyl/methylphenylsiloxane copolymer terminated with dimethylhexenylsilyl groups at both ends, polydimethyl/diphenylsiloxane copolymer terminated with dimethylhexenylsilyl groups at both ends, polymethylphenylsiloxane terminated with dimethylhexenylsilyl groups at both ends, polydimethyl/methylvinylsiloxane copolymer terminated with trimethylsilyl groups at both ends, polymethylphenylmethylvinylsiloxane terminated with trimethylsilyl groups at both ends, polydimethyl/methylhexenyl siloxane copolymer terminated with trimethylsilyl groups at both ends, polymethylphenyl/methylhexenyl siloxane copolymer terminated with trimethylsilyl groups at both ends, polydimethyl/methylvinylsiloxane copolymer terminated with dimethylvinylsilyl groups at both ends, polydimethyl/methylhexenyl siloxane copolymer terminated with dimethylvinylsilyl groups at both ends, polydimethyl/methylhexenylsiloxane copolymer terminated with dimethylhexenylsilyl groups at both ends, polymethylhexenyl siloxane terminated with silanol groups at both ends, polymethylhexenyl siloxane terminated with trimethylsilyl groups at both ends, polymethylhexenyl siloxane terminated with dimethylvinylsilyl groups at both ends, polymethylhexenyl siloxane terminated with dimethylhexenylsilyl groups at both ends, polydimethylsiloxane terminated with diphenylvinylsilyl groups at both ends, polydimethylsiloxane terminated with methylphenylvinylsilyl groups at both ends, 1,3-dimethyl-1,3-diphenyl-1,3-divinyl disiloxane, and the like.

Specific examples of the branched organopolysiloxane expressed by formula (3), and particularly formula (5), include polysiloxanes composed of M^{vi} (dimethylvinylsiloxy) units and T (methylsiloxy) units, polysiloxanes composed of M^{vi} units and Q (siloxy) units, polysiloxanes composed of M^{vi} units, M (trimethylsilyl) units and Q units, polysiloxanes composed of M^{vi} units, D (dimethylsiloxy) units and T units, polysiloxanes composed of M^{vi} units, M units and T units, polysiloxanes composed of M^{vi} units and T^{Ph} (phenylsiloxy) units, polysiloxanes composed of M^{vi} units, M units, and T^{Ph} units, polysiloxanes composed of M^{vi} units, D units and T^{Ph} units, polysiloxanes composed of M^{Hex} (dimethylhexenylsiloxy) units and T units, polysiloxanes composed of M^{Hex} units and Q units, polysiloxanes composed of M^{Hex} units, M units, and Q units, polysiloxanes composed of M^{Hex} units, D units, and T units, polysiloxanes composed of M^{Hex} units, M units, and T units, polysiloxanes composed of M^{Hex} units and T^{Ph} units, polysiloxanes composed of M^{Hex} units, M units and T^{Ph} units, polysiloxanes composed of M^{Hex} units, D units and T^{Ph} units, polysiloxanes composed of D^{Hex} (methylhexenylsiloxy) units and T units, polysiloxanes composed of M units, D^{Vi} (methylvinylsiloxy) units and T^{Ph} units, polysiloxanes composed of D^{Vi} units, D units and T^{Ph} units, polysiloxanes composed of D^{Vi} units and T^{Ph} units, polysiloxanes composed of M units, D^{Hex} units and T units, polysiloxanes composed of D^{Hex} units, D units and T units, polysiloxanes composed of D^{Hexa} units and T^{Ph} units, polysiloxanes composed of D^{Hexa} units, D units and T^{Ph} units, polysiloxanes composed of M units, D^{Hex} units, and T^{Ph} units, polysiloxanes composed of M units, D^{Hex} units, and Q units, polysiloxanes composed of M units and T^{Hex} (hexenylsiloxy) units, polysiloxanes composed of M units, D units, and T^{Hexa} units, polysiloxanes composed of D units and T^{Hex} units, polysiloxanes composed of T^{Hexa} units, polysiloxanes composed of T^{Hex} units and Q units, polysiloxanes composed of M units, T^{Hex} units, and Q units, polysiloxanes composed of T^{Hex} units and T units, polysiloxanes composed of T^{Hex} units and T^{Ph} units, and polysiloxanes composed of M units, T^{Hexa} units, and T^{Ph} units.

Specific examples of cyclic organopolysiloxanes expressed by formula (6) include 1,3,5,7-tetramethyl-1,3,5,7-tetravinylcyclotetrasiloxane, 1,3,5-trimethyl-1,3,5-trihexenylcyclotrisiloxane, 1,3,5,7-tetramethyl-1,3,5,7-tetrahexenylcyclotetrasiloxane, 1,3,5,7,9-pentamethyl-1,3,5,7,9-pentavinylcyclopentasiloxane, 1,3,5,7,9-pentamethyl-1,3,5,7,9-pentahexenylcyclopentasiloxane, cyclic trisiloxanes composed of methylvinylsiloxy groups and methylphenylsiloxy groups, and cyclic tetrasiloxanes composed of methylvinylsiloxy groups and methylphenylsiloxy groups.

The organopolysiloxanes expressed by the aforementioned formula (3), and more specifically any of formulas (4) to (6), can each be individually one type, or an arbitrary combination of two or more types as component (B).

Component (B) is particularly preferably an organopolysiloxane expressed by the above formula (4) or (5).

The compound recommended as component (B) is one compound or a combination of two or more compounds selected from the group consisting of polydimethyl/diphenylsiloxane copolymer terminated with dimethylvinylsilyl groups at both ends, polymethylphenylsiloxane terminated with dimethylvinylsilyl groups at both ends, polydimethylsiloxane terminated with methylphenylvinylsilyl groups at both ends, 1,3-dimethyl-1,3-diphenyl-1,3-divinyldisiloxane, polysiloxanes composed of M units, D^{Hexa} units, and T^{Ph} units, polysiloxanes composed of M units, D^{Vi} units, and T^{Ph} units, polysiloxanes composed of M^{vi} units and T^{Ph} units, and polysiloxanes composed of M^{vi} units, D units, and T^{Ph} units. Of these, polydimethyl/diphenylsiloxane copolymers terminated with dimethylvinylsilyl groups at both ends, polymethylphenylsiloxane terminated with dimethylvinylsilyl groups at both ends, and 1,3-dimethyl-1,3-diphenyl-1,3-divinyldisiloxane are particularly preferable.

### Component (C)

The ultraviolet light curable composition of the present invention may further contain, optionally, a compound (C) having one or more (meth)acryloxy group and no hydroxyl group in the molecule. There is no limitation on the molecular structure so long as this objective can be achieved, and the structure can be linear, branched, cyclic, box-shaped, or any other type.

The viscosity at 25° C. of component (C) is preferably 1 to 500 mPa·s, more preferably 1 to 100 mPa·s, particularly preferably 1 to 20 mPa·s, and most preferably 1 to 10 mPa·s.

Additionally, component (C) contains 1 to 6, preferably 1 to 4, and more preferably 1 to 3 (meth)acryloxy groups per molecule. In compounds with a plurality of (meth)acryloxy groups, there is no limitation on the positions of the (meth)acryloxy groups in a molecule, and the groups may be close together or far apart.

The aforementioned component (A) may be a single compound having one (meth)acryloxy group or a mixture of two or more compounds, each having one acryloxy group.

Furthermore, the aforementioned component (A) may be a mixture of one or more compounds having one (meth)acryloxy group and a compound having two or more (meth)acryloxy groups.

Specific examples of compounds with one (meth)acryloxy group include isoamyl acrylate, isoamyl methacrylate, octyl acrylate, octyl methacrylate, dodecyl acrylate, dodecyl methacrylate, lauryl acrylate, lauryl methacrylate, stearyl acrylate, stearyl methacrylate, diethyleneglycol monoethyl ether acrylate, diethyleneglycol monoethyl ether methacrylate, diethyleneglycol monomethyl ether acrylate, diethyleneglycol monomethyl ether methacrylate, 2-ethylhexyl acrylate, 2-ethylhexyl methacrylate, phenoxyethyl acrylate, phenoxyethyl methacrylate, diethyleneglycol monophenyl ether acrylate, diethyleneglycol monophenyl ether methacrylate, tetrahydrofurfuryl acrylate, tetrahydrofurfuryl methacrylate, isobornyl acrylate, isobornyl methacrylate, dicyclopentanyl acrylate, dicyclopentanyl methacrylate, dicyclopentenyl acrylate, dicyclopentenyl methacrylate, 3,3,5-trimethylcyclohexyl acrylate, and 3,3,5-tricyclohexyl methacrylate, polydimethylsiloxane terminated with an acryloxy functional group on one end, polydimethylsiloxane terminated with a methacryloxy functional group on one end, polydimethyldiphenylsiloxane terminated with an acryloxy functional group on one end, polydimethyldiphenylsiloxane terminated with a methacryloxy functional group on one end, (meth)acryloxy-functional branched organopolysiloxane, and the like. These may be used alone or in a mixture of two or more.

Examples of the (meth)acryloxy-functional branched organopolysiloxane include acryloxypropyl tristrimethylsiloxysilane, methacryloxypropyl tristrimethylsiloxysilane, acryloxypropyl tris(trimethylsilylethyldimethylsiloxy)silane, methacryloxypropyl tris(trimethylsilylethyldimethylsiloxy)silane, acryloxypropyl tris((tristrimethylsiloxysilyl)ethyldimethylsiloxy)silane, and methacryloxypropyl tris((tristrimethylsiloxysilyl)ethyldimethylsiloxy)silane. These may be used alone or in a combination of two or more.

Compounds with one (meth)acryloxy group can be used individually, or in combinations of two or more groups, in consideration of the viscosity of the compound, curability, hardness after curing, and the glass transition temperature. Of these, 2-ethylhexyl acrylate, 2-ethylhexyl methacrylate, isobornyl acrylate, isobornyl methacrylate, dicyclopentanyl acrylate, dicyclopentanyl methacrylate, and (meth)acryloxypropyl tristrimethylsiloxysilane are preferably used, and 2-ethylhexyl acrylate, isobornyl acrylate, dicyclopentanyl acrylate, and (meth)acryloxypropyl tristrimethylsiloxysilane are particularly preferably used.

Specific examples of compounds having two or more (meth)acryloxy groups include diethylene glycol diacrylate, diethylene glycol dimethacrylate, triethylene glycol diacrylate, triethylene glycol dimethacrylate, neopentyl glycol diacrylate, neopentyl glycol dimethacrylate, polyethylene glycol diacrylate, polyethylene glycol dimethacrylate, 1,4-bis(acryloyloxy)butane, 1,4-bis(methacryloyloxy)butane, 1,6-bis(acryloyloxy)hexane, 1,6-bis(methacryloyloxy)hexane, 1,9-bis(acryloyloxy)nonane, 1,9-bis(methacryloyloxy)nonane, tricyclodecane dimethanol diacrylate, tricyclodecane dimethanol, dimethacrylate, trimethylolpropane triacrylate, trimethylolpropane trimethacrylate, tris(2-acryloyloxy)ethyl isosialylate, tris(2-methacryloyloxy)ethyl isosialylate, tris(2-acryloyloxy)ethyl isosialylate, tris(2-methacryloyloxy)ethyl isosialylate, pentaerythritol tetraacrylate, pentaerythritol tetramethacrylate, polydimethylsiloxane having acryloxy functionality at both ends, polydimethylsiloxane having methacryloxy functionality at both ends, polydimethyldiphenylsiloxane copolymer having acryloxy functionality at both ends, and polydimethyldiphenylsiloxane copolymer having methacryloxy functionality at both ends.

Compounds with two or more (meth)acryloxy groups can be used individually, or in combinations of two or more groups, in consideration of the viscosity of the compound, curability, compatibility with the aforementioned compound having one acryloxy group, hardness after curing, and the glass transition temperature. Diethylene glycol diacrylate, diethylene glycol dimethacrylate, 1,6-bis(acryloyloxy)hexane, 1,6-bis(methacryloyloxy)hexane, tricyclodecane dimethanol diacrylate, tricyclodecane dimethanol dimethacrylate, trimethylolpropane triacrylate, trimethylolpropane trimethacrylate, pentaerythritol tetraacrylate, pentaerythritol tetramethacrylate, and polydimethylsiloxane having acryloxy functionality at both ends are preferably used, but compounds not having silicon atoms, such as diethylene glycol diacrylate, diethylene glycol dimethacrylate, 1,6-bis(acryloyloxy)hexane, 1,6-bis(methacryloyloxy)hexane, tricyclodecane dimethanol diacrylate, tricyclodecane dimethanol dimethacrylate, trimethylolpropane triacrylate, trimethylolpropane trimethacrylate, pentaerythritol tetraacrylate, or pentaerythritol tetramethacrylate, are more preferable, and tricyclodecane dimethanol diacrylate, trimethylolpropane triacrylate, or pentaerythritol tetraacrylate are particularly preferable.

Furthermore, taking into consideration the above physical properties, a combination of a compound having two or more (meth)acryloxy groups and a compound having one (meth)acryloxy group can be used in components (A) and (C). In this case, the two can be combined in any ratio, but usually, [total amount of compounds having two or more (meth)acryloxy groups in components (A) and (C)]/[total amount of compounds having one (meth)acryloxy group in components (A) and (C)] is in a range of 1/99 to 75/25 (mass ratio), may be in a range of 1/99 to 50/50, or may be in a range of 1/99 to 30/70. This is because if the ratio of the compound having two or more (meth)acryloxy groups is too high, a cured product will tend to be hard and brittle.

### [Mixing Ratio of Components (A)/(B)]

The mixing ratio of component (A) and component (B) is 1 to 99 mass % for component (A) and 1 to 99 mass % for component (B), relative to 100 mass % in total for components (A) and (B). A preferred ratio of component (A) is 1 mass % or more and 90 mass % or less, more preferably 1 mass % or more and 70 mass % or less, and even more preferably 2 mass % or more and 50 mass % or less, based on the total amount of components (A) and (B). When the ratio of components (A) and (B) is within this range, a material can be designed to have an appropriate viscosity for the curable composition, maintain good ultraviolet light curability, and provide a cured product with good adhesion.

### [Ratio of Component (A) in the Curable Composition]

The ratio of component (A) in the entire curable composition is preferably 1 to 70 mass %, more preferably 5 to 50 mass %, and even more preferably 10 to 30 mass %, relative to 100 mass % of the total amount of the composition. The adhesiveness of the cured product can be improved by increasing the proportion of component (A). On the other hand, if the ratio of component (A) is too high, the transparency of the curable composition and the resulting cured product may be impaired. When the ratio of components (A) is within this range, a material can be designed to have an appropriate viscosity for the curable composition, maintain good ultraviolet light curability, and provide a cured product with good adhesion and transparency.

### [Ratio of Silicon-Containing Component in the Curable Composition]

Component (B) in the composition of the present invention is a silicon-containing component, and component (C) may also be a silicon-containing component. The ratio of the silicon-containing component in the entire curable composition is preferably less than 50 mass %, more preferably from 5 to 45 mass %, and even more preferably from 10 to 40 mass %, based on 100 mass % of the total amount of the composition. When the ratio of the silicon-containing component is within the aforementioned range, the viscosity of the curable composition will be appropriate, good ultraviolet light curability is maintained, and a material can be designed with good transparency and mechanical properties, particularly tensile properties, of the resulting cured product.

The amount of component (A), component (B) and component (C) in the ultraviolet light curable composition of the present invention are in a ranges of 1 to 99 parts by mass, 99 to 1 part by mass, and 0 to 80 parts by mass, respectively, when the total mass of the composition is 100 parts by mass. Furthermore, if the total mass of the composition is 100 parts by mass, the sum of the amounts of components (A), (B), and (C) is preferably 90 parts by mass or more, particularly preferably in a range of 90 to 99.9 parts by mass, and particularly preferably in the range of 90 to 99 parts by mass. In other words, a suitable ultraviolet light curable composition is mostly a composition containing component (A), component (B), and optional component (C). However, the present composition may contain another component to be described later. Note that component (C) is an optional component in the present composition, and the amount may be 0 parts by mass.

### [Hydroxyl Group Concentration in the Curable Composition]

The concentration of hydroxyl groups in the ultraviolet light curable composition of the present invention is an important guideline for designing a cured product with good adhesiveness. When the number of moles of hydroxyl groups in 100 g of the total curable composition is 5 mmol or more and 150 mmol or less, the composition maintains good ultraviolet light curability, and the cured product has high adhesiveness. If the concentration of hydroxyl groups is too high, the transparency of the curable composition and the resulting cured product may be impaired. The number of moles of hydroxyl groups is more preferably in a range of 20 to 120 mmol.

### [Organic Solvent-Free]

The ultraviolet light curable composition of the present invention can achieve a suitable viscosity for the aforementioned coating agent without substantial use of an organic solvent and by using each of the aforementioned components, and the ultraviolet light curable composition substantially does not include an organic solvent. In the present specification, the phrase “essentially not containing an organic solvent” means that the amount of organic solvent is less than 0.1 mass % of the total composition, preferably less than or equal to the analytical limit of analytical methods such as gas chromatography or the like. In the present invention, the desired viscosity can be achieved without the use of organic solvents by adjusting the molecular structure and molecular weight of components (A) and (B), and by optionally adding component (C).

In addition to the components (A) and (B) above, a photopolymerization initiator can be added to the ultraviolet light curable composition of the present invention if desired. A photo-radical polymerization initiator can be used as the photoinitiator. The photoradical polymerization initiator generates free radicals by irradiating ultraviolet rays or electron beams, which trigger a radical polymerization reaction, to cure the composition of the present invention. When the composition of the present invention is cured by electron beam irradiation, a polymerization initiator is normally not required.

The photoradical polymerization initiators are known to be broadly classified into photocleaving and hydrogen extracting types. However, the photoradical polymerization initiator used in the composition of the present invention can be selected arbitrarily from those known in the technical field, and is not limited to any particular one. Examples of photoradical polymerization initiators include, but are not limited to, acetophenone, p-anisyl, benzyl, benzoin, benzophenone, 2-benzoylbenzoic acid, 4,4′-bis(diethylamino)benzophenone, 4,4′-bis(dimethylamino) benzophenone, benzoin methyl ether, benzoin isopropyl ether, benzoin isobutyl ether, benzoin ethyl ether, 4-benzoylbenzoic acid, 2,2′-bis(2-chlorophenyl)-4,4′,5,5′-tetraphenyl-1,2′-biimidazole, methyl 2-benzoylbenzoate, 2-(1,3-benzodioxol-5-yl)-4,6-bis(trichloromethyl)-1,3,5-triazine, 2-benzyl-2-(dimethylamino)-4′-morpholinobutyrophenone, (±)-camphorquinone, 2-chlorothioxanthone, 4,4′-dichlorobenzophenone, 2,2-diethoxyacetophenone, 2,2-dimethoxy-2-phenylacetophenone, 2,4-diethylthioxanthene-9-one, diphenyl(2,4,6-trimethylbenzoyl)phosphine oxide, ethyl(2,4,6-trimethylbenzoyl)phenyl phosphinate, 1,4-dibenzoylbenzene, 2-ethylanthraquinone, 1-hydroxycyclohexylphenyl ketone, 2-hydroxy-2-methylpropiophenone, 2-hydroxy-4′-(2-hydroxyethoxy)-2-methylpropiophenone, 2-isopropylthioxanthone, lithium phenyl(2,4,6-trimethylbenzoyl)phosphinate, 2-methyl-4′-(methylthio)-2-morpholinopropiophenone, 2-isonitrosopropiophenone, 2-phenyl-2-(p-toluenesulfonyloxy)acetophenone, and phenylbis(2,4,6-trimethylbenzoyl)phosphine oxide, and the like. Furthermore, in addition to the aforementioned compounds, examples of the photoradical polymerization initiators can include Omnirad (registered trademark) 651, 184, 1173, 2959, 127, 907, 369, 369E, and 379EG (alkylphenone photopolymerization initiators, IGM Resins B.V.); Omnirad (registered trademark) TPO H, TPO-L, and 819 (acyl phosphine oxide photopolymerization initiators, IGM Resins B.V.); Omnirad (registered trademark) MBF and 754 (intramolecular hydrogen extracting type photopolymerization initiators, IGM Resins B.V.); Irgacure (registered trademark) OXE01 and OXE02 (oxime ester non-associative polymerization initiator, BASF); and the like.

While the amount of the photoradical polymerization initiator added to the composition of the present invention is not particularly limited so long as the intended photopolymerization reaction or photocuring reaction occurs, it is generally used at an amount of 0.01 to 5 mass %, and preferably 0.05 to 1 mass % relative to the total mass of the composition of the present invention.

Furthermore, a photosensitizer may be used in combination with the aforementioned photoradical polymerization initiator. Use of a sensitizer can increase the photon efficiency of the polymerization reaction, and is particularly effective when the coating thickness of the composition is relatively thick or when a relatively long-wavelength LED light source is used, because use of longer wavelength light for the polymerization reaction compared to only using a photoinitiator is feasible.

While not limited thereto, examples of known photosensitizing agents include anthracene-based compounds, phenothiazine-based compounds, perylene-based compounds, cyanine-based compounds, melocyanine-based compounds, coumarin-based compounds, benzylidene ketone-based compounds, and (thio)xanthene- or (thio)xanthone-based compounds such as isopropylthioxanthone, 2,4-diethylthioxanthone, alkyl-substituted anthracenes, squarylium-based compounds, (thia)pyrylium-based compounds, porphyrin-based compounds, and the like, and any photosensitizing agent can be used in the curable composition of the present invention.

The cured product obtained from the curable composition of the present invention can be designed so that desired physical properties of the cured product and the curing speed of the curable composition are obtained and the viscosity of the curable composition will be a desired value depending on the molecular chain length and molecular structure of components (A) and (B), the number of (meth)acryloxy groups per molecule of component (A), the number of alkenyl groups per molecule of component (B), and the molecular chain length, molecular structure, and number of (meth)acryloxy groups per molecule of component (C) which is optionally added. Furthermore, the cured product obtained by curing the curable composition of the present invention is also included in the scope of the present invention. Furthermore, the shape of the cured product obtained from the composition of the present invention is not particularly limited, and it may be a thin film coating layer, may be a sheet-like molded product or the like, may be injected into a specific site in an uncured state and then cured to form a filling material, or may be used as a sealing material for a laminated body, display device, or the like or as an intermediate layer. The cured product obtained from the composition of the present invention is preferably in the form of an injection molded protective adhesive layer and a thin film coating layer, and particularly preferably is a thin film insulating coating layer.

The curable composition of the present invention is suitably used as a coating agent, potting agent, or adhesive, and particularly as an insulating coating agent, insulating adhesive, or potting agent for electronic and electrical devices.

The cured product obtained by curing the curable composition of the present invention is characterized by excellent mechanical properties, and particularly adhesive strength. Furthermore, a material can be designed with good tensile elongation by optimizing the structure of the curable composition as described above.

For example, if a test piece having a thickness of 0.5 mm is used and evaluated at a tensile speed of 50 mm/min at 25° C., the test piece usually has a tensile elongation of 20% or more. By optimizing the curable composition, the tensile elongation of the cured product can be increased to 100% or more, and can be used as a layer forming material for a flexible display.

If desired, the cured product obtained by curing the curable composition of the present invention can be designed to have a dielectric constant of less than 3.0, and the curable composition of the present invention can also be used to form a coating layer having a low dielectric constant.

If the curable composition of the present invention is used as an injection molding material or a coating agent, in order to provide the composition with suitable fluidity and workability for application to a substrate, the viscosity of the entire composition is preferably a value of 500 mPa·s or less at 25° C., as measured using an E-type viscometer. When used as an injection molding material, the viscosity is preferably 300 mPa·s or less, particularly 100 mPa·s or less, although this depends on the gap into which the composition is injected. On the other hand, when used as a coating agent, the preferred viscosity range is 5 to 60 mPa·s, more preferably 5 to 30 mPa·s, and particularly preferably 5 to 20 mPa·s, from the perspective of application of inkjet printing methods which are rapidly coming into practical use. The viscosity of the entire curable composition can be adjusted to the desired viscosity by using at an optimal ratio compounds with a preferred viscosity, as each component so that the viscosity of the entire composition has the desired viscosity. On the other hand, if the curable composition of the present invention is used as an adhesive, any processing method selected from injection molding methods, spin coating methods, and inkjet printing methods can be applied, and the composition preferably has a suitable viscosity for each of the aforementioned methods.

### [Additional Optional Additives]

In addition to the above components, other additives may be added to the composition of the present invention, if desired. Examples of additives that can be used include leveling agents, wettability improving agents, silane coupling agents, ultraviolet light absorbers, antioxidants, polymerization inhibitors, and fillers (functional fillers such as reinforcing fillers, insulating fillers, and thermally conductive fillers). If necessary, an appropriate additive can be added to the composition of the present invention.

Furthermore, a thixotropy-imparting agent may also be added to the composition of the present invention if necessary, particularly when used as a potting agent or sealing material.

### [Use]

When the ultraviolet light curable organopolysiloxane composition of the present invention is irradiated with a high-energy beam, such as ultraviolet rays or the like, a radical polymerization reaction can proceed and a cured product can be formed.

Examples of available high energy beams include ultraviolet light rays, gamma rays, X-rays, alpha rays, electron beams, and the like. In particular, examples include ultraviolet light rays, X-rays, and electron beams irradiated from a commercially available electron beam irradiating device. Of these, ultraviolet light rays are preferable from the perspective of efficiency of catalyst activation, and ultraviolet rays within a wavelength range of 280 to 405 nm are preferable from the perspective of industrial use. The dose of ultraviolet light is preferably within a range of 100 mJ/cm² to 10 J/cm² in terms of the integrated dose at a wavelength of 365 nm or 405 nm.

The curable composition of the present invention has low viscosity, and is particularly useful as a material for forming an insulating layer for various articles, particularly electronic and electrical devices. The composition of the present invention can be coated on a substrate or sandwiched between two substrates, at least one of which includes a material that allows ultraviolet rays or electron beams to pass, and the composition can be cured by irradiating ultraviolet rays or electron beams to form an insulating layer. In this case, the composition of the present invention can be patterned when coated on a substrate, and then the composition can be cured. Alternatively, the composition can be coated on a substrate, and cured and uncured portions can be left during curing by ultraviolet rays or electron beam irradiation. Thereafter, an uncured portion can be removed with a solvent to form an insulating layer having a desired pattern. In particular, when the cured layer according to the present invention is an insulating layer, the layer can be designed to have a low dielectric constant of less than 3.0.

The curable composition of the present invention provides favorable transparency adhesion properties of the cured product obtained therefrom, and is particularly suitable as a material for forming an insulating layer for touch panels, displays and other display devices. In this case, an arbitrary desired pattern may be formed as described above if necessary on the insulating layer. Therefore, a display device such as touch panel, display, or the like containing an insulating layer obtained by curing the ultraviolet light curable composition of the present invention is also an aspect of the present invention.

Furthermore, the curable composition of the present invention can also be used to form an insulating coating layer (insulating film) by curing after coating an article. Therefore, the composition of the present invention can be used as an insulative coating agent. Furthermore, a cured product formed by curing the curable composition of the present invention can be used as an insulating coating layer.

An insulating film formed from the curable composition of the present invention can be used for various applications. In particular, use is possible as a component member of an electronic device or as a material used in a process of manufacturing the electronic device. Electronic devices include semiconductor devices, magnetic recording heads, and other electronic apparatuses. For example, the curable composition of the present invention can be used as an insulating film for semiconductor devices, such as LSI, system LSI, DRAM, SDRAM, RDRAM, D-RDRAM, and multi-chip module multilayer wiring boards, an interlayer insulating film for semiconductors, an etching stopper film, a surface protective film, a buffer coat film, a passivation film in LSI, a cover coat for flexible copper-clad boards, a solder resist film, and a surface protective film for optical devices.

Furthermore, the ultraviolet light curable composition of the present invention can be used as a coating agent, or as a potting agent, and particularly as an insulative potting agent for electronic devices and electrical devices.

The ultraviolet light curable composition of the present invention can be used as a material for forming a coating layer on a surface of a substrate, particularly using an inkjet printing method. In this case, the composition of the present invention particularly preferably contains a wettability improving agent.

The present invention is further described below on the basis of Examples, but the present invention is not limited to the Examples below.

### EXAMPLES

The ultraviolet light curable composition of the present invention and a cured product thereof will be described in further detail using examples. Furthermore, measurements and evaluations in the Examples and Comparative Examples were conducted as follows.

### [Viscosity of Curable Composition and Each Component]

The viscosity (mPa·s) of the composition at 25° C. was measured using a rotational viscometer (E-type viscometer VISCONIC EMD, manufactured by Tokimec Inc.).

### [Appearance of Curable Composition and Cured Product Obtained Therefrom]

The curable composition and the cured product obtained therefrom were visually observed to evaluate the appearance including transparency.

### [Hydroxyl Group Concentration of Curable Composition]

The hydroxyl group concentration (mmol/100 g) in 100 g of the curable composition was calculated using the mass ratio of component (A) in the composition, the mass ratio of hydroxyl groups in component (A), and the chemical formula weight of the hydroxyl groups (17.01).

### [Preparation of Curable Composition]

Each material was placed in a brown plastic container at the amounts listed in Table 1 and Table 2, and mixed well using a planetary mixer to prepare the curable composition.

### [Ultraviolet Light Curability of Curable Composition]

Approximately 0.1 g of the liquid curable composition was sandwiched between two 4 mm thick alkaline glass substrates (25×75×4 mm³) arranged in a cross shape, with a 0.13 um thick spacer therebetween, to prepare a cross-shaped sandwich test piece formed as glass/curable composition/glass. LED light with a wavelength of 405 nm was irradiated with an energy amount of 2 J/cm² from the outside through one glass substrate. The ultraviolet light curability was evaluated based on the following criteria.
Good: The two glass substrates are firmly bonded together, and no residual liquid components are observed even when the bonded portions are peeled apart.
Acceptable: The two glass substrate are adhered together, but can be easily peeled apart with a little force, and liquid components remain in addition to the cured product.
Poor: The two glass substrate are not bonded together, and the liquid composition remains.

### [Curing of Curable Composition and Preparation of Tensile Test Piece]

A spacer having a thickness of 0.5 mm was placed between two glass substrates with PET films coated with a fluoropolymer release agent, and about 0.8 g of the curable composition was injected into the gap. By irradiating LED light having a wavelength of 405 nm at an energy intensity of 2 J/cm² from the outside through one glass substrate, the composition was cured to prepare a plate-shaped cured product having a length of 50 mm and a thickness of 0.5 mm. The short pieces were trisected to prepare 10×50×0.5 (thick) mm³ strip-shaped tensile test pieces.

### [Tensile Properties of Organopolysiloxane Cured Product]

Tensile test pieces prepared from the above organopolysiloxane cured products were used and evaluated at 25° C. and a test speed of 50 mm/min using an autograph AGS-X manufactured by Shimadzu Corporation. The measured value was recorded as tensile elongation at break (unit: %).

### [Adhesive Strength of Organopolysiloxane Cured Product]

A cross-shaped test piece made of the organopolysiloxane cured product obtained in the aforementioned ultraviolet light curability evaluation was used, and the upper glass substrate of the horizontally placed test piece was pulled vertically using the aforementioned Autograph AGS-X to perform an evaluation. The test temperature was 25° C., the test speed was 1 mm/min, and the measured value was recorded as the stress at break (units: MPa).

### [Curing of Curable Composition and Preparation of Sample for Dielectric Constant Measurement]

A mold having a thickness of 1 mm having circular holes with an inner diameter of 40 mm was placed on a PET film coated with a fluoropolymer release agent, and approximately 1.3 g of the curable composition was poured into a hole thereof. A PET film similar to that described above was placed over the composition, and a 10 mm thick glass plate was placed thereon. The composition was cured by irradiating it with LED light having a wavelength of 405 nm with an energy amount of 2 J/cm² from above, producing a disk-shaped organopolysiloxane cured product having a diameter of 40 mm and a thickness of 1 mm.

### [Dielectric Constant of Organopolysiloxane Cured Product (Example 5)]

A tin foil having a diameter of 33 mm and a thickness of 0.007 mm was pressed onto both surfaces of the prepared organopolysiloxane cured product. In order to improve close-fitting properties between the cured product and the foil, a small amount of silicone oil, if necessary, was used for pressing. The capacitance at room temperature and 100 KHz was measured by an E4990A precision impedance analyzer manufactured by Keysight Technologies to which a parallel plate electrode having a diameter of 30 mm was connected. The dielectric constant was calculated using measured capacitance values, separately measured thicknesses of the cured product, and electrode area values. The dielectric constant of the organopolysiloxane cured product in Example 5 shown in the table below was 2.9, indicating that a cured product with a low dielectric constant was obtained.

### EXAMPLES AND COMPARATIVE EXAMPLES

The ultraviolet light curable compositions were prepared at the compositions (parts by mass) shown in Table 1 and Table 2 using each of the following components.
(A1) 4-Hydroxybutyl acrylate (monofunctional)
(A2) 3-Acryloyloxy-2-hydroxypropyl methacrylate (bifunctional)
(A3) Acrylic acid (monofunctional)
(B1) Branched polysiloxane expressed by M_{0.18}D^{Hex}_{0.50}T^{Ph}_{0.32} (average number of functional groups: 8; viscosity: 140 mPa·s)
(B2) Dimethylvinyl polymethylphenyl siloxane terminated at both ends (functional groups: 2; average number of silicon atoms: 28; viscosity: 3000 mPa·s)
(C1) Isobornyl acrylate (monofunctional)
(C2) Ethylhexyl acrylate (monofunctional)
(C3) Trimethylolpropane triacrylate (trifunctional)
(D1) OMNIRAD TPO-L (manufactured by IGM Resins)
(D2) OMNIRAD TPO (made by IGM Resins)
(D3) Dibutylhydroxytoluene

TABLE 1

| | | | Comparative |
|---|---|---|---|
| Component | Example 1 | Example 2 | Example 1 |
| (A1) | 10.1 | | |
| (A2) | | 5.1 | |
| (B1) | 39.7 | 41.9 | 43.2 |
| (C1) | 49.4 | 52.2 | 56.0 |
| (D1) | 0.5 | 0.5 | 0.5 |
| (D3) | 0.3 | 0.3 | 0.3 |
| Total | 100.0 | 100.0 | 100.0 |
| Appearance of curable | Transparent | Transparent | Transparent |
| composition | | | |
| Viscosity of composition | 15 | 17 | 17 |
| mPa · s | | | |
| Hydroxyl concentration in | 70 | 47 | 0 |
| composition mmol/100 g | | | |
| Appearance of cured product | Transparent | Transparent | Transparent |
| Adhesive strength of cured | >1.0 | >1.0 | 0.5 |
| product | | | |
| MPa | | | |

TABLE 2

| | | | | | Comparative |
|---|---|---|---|---|---|
| Component | Example 3 | Example 4 | Example 5 | Example 6 | Example 2 |
| (A1) | 3.0 | 15.0 | 10.0 | | |
| (A3) | | | | 65.5 | |
| (B2) | 25.8 | 20.9 | 24.7 | 33.7 | 25.8 |
| (C1) | 63.3 | 63.3 | 55.0 | | 63.3 |
| (C2) | 7.1 | | 4.3 | | 10.1 |
| (C3) | | | 5.2 | | |
| (D2) | 0.5 | 0.5 | 0.5 | 0.5 | 0.5 |
| (D3) | 0.3 | 0.3 | 0.3 | 0.3 | 0.3 |
| Total | 100.0 | 100.0 | 100.0 | 100.0 | 100.0 |
| Appearance of curable | Transparent | Transparent | Transparent | Transparent | Transparent |
| composition | | | | | |
| Viscosity of composition | 17 | 16 | 19 | 6 | 16 |
| mPa · s | | | | | |
| Hydroxyl concentration in | 21 | 104 | 69 | 909 | 0 |
| composition mmol/100 g | | | | | |
| Appearance of cured | Transparent | Transparent | Transparent | Translucent | Transparent |
| product | | | | | |
| Adhesive strength of | 0.4 | 0.5 | 0.7 | >1.0 | 0.3 |
| cured product | | | | | |
| MPa | | | | | |

TABLE 3

| | Example | Comparative | Example | Comparative |
|---|---|---|---|---|
| | 1 | Example 1 | 3 | Example 2 |
| Tensile | 225 | 180 | 420 | 425 |
| elongation | | | | |
| at break | | | | |
| (%) of cured | | | | |
| product | | | | |

As shown in Table 1 and Table 2, the ultraviolet light curable compositions of the present invention (Examples 1 to 6) have viscosities at 25° C. that are suitable for application onto substrates as injection molding materials and coating agents, especially by inkjet printing.

Furthermore, the cured product obtained from the composition of the present invention has favorable adhesion, as shown in Table 3, and also has high tensile elongation and excellent flexibility. Furthermore, the cured product obtained from the composition of the present invention (particularly Example 5) exhibits low dielectric properties.

On the other hand, the ultraviolet light curable compositions according to the comparative examples not containing component (A) (Comparative Examples 1 and 2) have insufficient adhesion to the substrate of the obtained cured product as compared to compositions containing component (A), and were unsuitable as a material for forming an insulating layer of a display device such as a display.

### INDUSTRIAL APPLICABILITY

The ultraviolet light curable composition of the present invention is particularly suitable for the applications described above, and particularly as a material for forming an insulating layer for touch panels and displays and other display devices, and particularly flexible displays.

1. An ultraviolet light curable composition, comprising:
(A) 1 to 99 parts by mass of a compound having one or more (meth)acryloxy groups and hydroxyl groups in each molecule and having no silicon atoms;
(B) 1 to 99 parts by mass of an organopolysiloxane having two or more alkenyl groups in each molecule and having no ultraviolet light curable functional groups; and
(C) 0 to 80 parts by mass of a compound having one or more (meth)acryloxy groups in each molecule and having no hydroxyl groups;
each based on 100 mass parts of the total mass of the composition;
wherein the composition is substantially free of organic solvent.

2. The ultraviolet light curable composition according to claim 1, wherein component (A) is expressed by the following formulas (1A) or (1B): 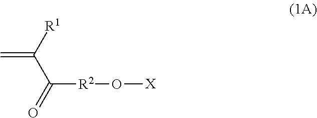
where R¹ is a hydrogen atom or a methyl group, R² is a divalent linking group expressed by the following formula (2A), X is a hydrogen atom, an alkyl group having 1 to 20 carbon atoms, a cycloalkyl group, an arylalkyl group, an aryl group, or a (meth)acrylic group, R³ is a hydrogen atom, a methyl group, or an ethyl group, y is a hydroxyl group or a hydroxymethyl group, a is an integer from 0 to 3, b is 0 or 1, c is an integer from 0 to 3, d is an integer from 0 to 5, and * is a bonding site to the carbonyl group; provided one or more hydroxyl groups are included in each molecule; 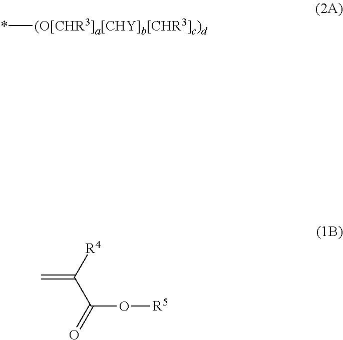
where R⁴ is a monovalent group expressed by the following formula (2B), R⁵ and R⁶ independently represent an alkyl group, a cycloalkyl group, an arylalkyl group, or an aryl group having 1 to 20 carbon atoms, e is an integer from 0 to 3, and ** is a bonding site to a carbon-carbon double bond;

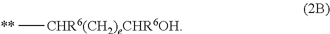

3. The ultraviolet light curable composition according to claim 1, wherein the viscosity of the entire composition, as measured at 25° C. using an E-type viscometer, is 500 mPa·s or less.

4. The ultraviolet light curable composition according to claim 1, wherein component (B) is a linear, branched, or cyclic organopolysiloxane expressed by the average compositional formula: 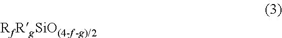
wherein, R is an alkenyl group;
R′ represents a group selected from monovalent hydrocarbon groups excluding alkenyl groups, hydroxyl groups, and alkoxy groups;
f and g are numbers that satisfy the following conditions: 1≤f+g≤3 and 0.05≤f/(f+g)≤1.0; and there are at least two R's in each molecule.

5. The ultraviolet light curable composition according to claim 1, wherein the organopolysiloxane of component (B) is one or more type of organopolysiloxane having at least two 2-alkenyl groups in each molecule, selected from the group consisting of:
organopolysiloxanes expressed by formula (4): 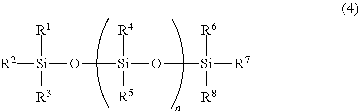
wherein, of all R¹ to R⁸ groups, at least two alkenyl groups are present in each molecule; the remaining R¹ to R⁸ are independently an unsubstituted or fluorine-substituted monovalent hydrocarbon group, a hydroxyl group, or an alkoxy group; and n is a number in a range of 0 to 1000, inclusively;
branched organopolysiloxanes expressed by average unit formula (5): 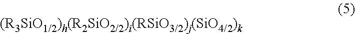
wherein each R is independently a group selected from alkenyl groups and unsubstituted or fluorine-substituted monovalent hydrocarbon groups, at least two of all R's are alkenyl groups, (j+k) is a positive number, h is 0 or a positive number, and i is a number in a range of 0 to 1004; and
cyclic organopolysiloxanes expressed by the following formula (6): 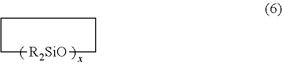
wherein each R is independently a group selected from alkenyl groups and unsubstituted or fluorine-substituted monovalent hydrocarbon groups, x is an integer from 3 to 10, and at least two alkenyl groups are provided in each molecule;
as well as mixtures of these organopolysiloxanes.

6. The ultraviolet light curable composition according to claim 5, wherein component (B) is an organopolysiloxane expressed by formula (4) or a branched organopolysiloxane expressed by formula (5).

7. The ultraviolet light curable composition according to claim 1, wherein component (B) is an organopolysiloxane having an aromatic hydrocarbon group with 6 to 20 carbon atoms.

8. The ultraviolet light curable composition according to claim 1, wherein component (C) is present and is one or more compounds having one (meth)acryloxy group, one or more compounds having two or more (meth)acryloxy groups, or a mixture of one or more compounds having one (meth)acryloxy group and one or more compound having two or more (meth)acryloxy groups.

9. The ultraviolet light curable composition according to claim 1, wherein component (C) is present and is a compound having one (meth)acryloxy group or a mixture of two or more compounds having one (meth)acryloxy group.

10. The ultraviolet light curable composition according to claim 1, wherein a portion or all of component (A) and component (C) are compounds having an acryloxy group.

11. The ultraviolet light curable composition according to claim 1, wherein component (A) is hydroxyalkyl (meth)acrylate.

12. The ultraviolet light curable composition according to claim 1, wherein the amount of aromatic hydrocarbon groups having 6 to 20 carbon atoms in component (B) is 10 mol % or more of all substituents on silicon atoms.

13. The ultraviolet light curable composition according to claim 1, wherein the viscosity of the entire composition, as measured at 25° C. using an E-type viscometer, is in a range of 5 to 60 mPa·s.

14. The ultraviolet light curable composition according to claim 1, wherein the number of moles of hydroxyl groups per 100 g of the total composition is 5 mmol or more and 150 mmol or less.

15. An insulating coating agent or insulating adhesive, comprising the ultraviolet light curable composition according to claim 1.

16. A cured product of the ultraviolet light curable composition according to claim 1.

17. A method of fer-using a cured product of the ultraviolet light curable composition according to claim 1 as an insulating coating layer or an insulating adhesive layer.

18. A display device, comprising a layer of a cured product of the ultraviolet light curable composition according to claim 1.
